(19) United States
(12) Patent Application Publication
(10) Pub. No.: US 2013/0071551 A1
(43) Pub. Date: Mar. 21, 2013

(54) COATING METHOD AND APPARATUS

(71) Applicants: Markku Rajala, Vantaa (FI); Olli Pekonen, Espoo (FI)

(72) Inventors: Markku Rajala, Vantaa (FI); Olli Pekonen, Espoo (FI)

(73) Assignee: BENEQ OY, VANTAA (FI)

(21) Appl. No.: 13/639,054

(22) PCT Filed: Mar. 2, 2011
(86) PCT No.: PCT/FI11/50176

§ 371 Date: Oct. 19, 2012

(30) Foreign Application Priority Data
Apr. 20, 2010 (FI) 20105423

(51) Int. Cl. C23C 16/448

(52) U.S. Cl. CPC C23C 16/4486
USPC 427/8; 427/248.1; 118/712; 427/255.28

(57) ABSTRACT

A coating process and apparatus; the apparatus including a unit for forming a mixture that includes at least one precursor of a surface reaction, a unit for atomizing the mixture into droplets, a unit for transporting the droplets of mixture towards a surface of a substrate to be coated with the surface reaction. The unit for forming a mixture are adjusted to mix to the mixture a liquid carrier substance, which is not a precursor of the surface reaction, and the boiling point of which in the defined process space is lower than the boiling point of the precursor of the surface reaction. The proposed arrangement improves both speed and quality of the coating process.

### FIELD OF THE INVENTION

The present invention relates to coating, and more particularly to a coating method and apparatus according to the respective preambles of the independent claims.

### BACKGROUND OF THE INVENTION

Coating refers generally to a process where a solid layer of coating substance is deposited on a substrate. In many industrially interesting applications, the coating layer is very thin, typically ranging from fractions of a nanometre (monolayer) to some micrometres in thickness.

One generally known coating process is based on chemical vapor deposition (CVD) reaction, where the substrate is exposed to one or more vapor phase chemical precursors that react and/or decompose on the surface of the substrate to produce the deposited layer. A known variant of the CVD process is Aerosol-Assisted Chemical Vapor Deposition (AACVD) where a liquid precursor solution is atomized into aerosol droplets that are distributed throughout a gaseous medium. The resulting aerosol is transported into a heated zone, where the droplets undergo a rapid vaporization and/or decomposition and form a precursor vapor at an increased temperature. The vaporized precursor may then go through one or more various decomposition and/or chemical reactions resulting in the desired layer structure.

The AACVD process is typically implemented in a defined process space, like a reaction chamber, into which the aerosol of droplets and the gaseous medium are introduced. The volume and pressure of the process space are thus well defined, so by managing temperatures and droplet concentrations, the vaporization of the droplets is typically adjusted to take place relatively close to the surface to be coated.

Another known coating method is based on impaction based coating. This coating method is carried out by transporting liquid droplets towards a surface of a substrate such that the liquid droplets comprising the precursors collide on the surface of the substrate. The surface reactions occur in liquid phase on the substrate surface for forming a coating.

A problem in the conventional methods and devices is to find such a combination of the aerosol composition and reactor configuration that both quality and speed requirements of industrially applicable coating processes can be met. If the droplets are arranged to vaporize relatively far away from the surface of the substrate, the precursors are early enough vaporized and therefore in desired form for the designed decomposition and/or chemical reactions. However, transportation of precursors in gas phase is less efficient than in liquid phase, so the concentration of the precursors in the vicinity of the surface of the substrate is relatively low, and the rate of material transfer from the vapor to the surface layer is often too slow for industrial applications. In addition, reactions that take place in the gas phase typically form precursor aggregates, which do not adhere well to the surface but create low-density layers with excessive amount of defects. If the droplets vaporize too early on their way towards the substrate to be coated, the quality of the resulting coating does not necessarily meet the levels required in industrial use. Consequently, the droplets should preferably remain in liquid form as far as possible on their way towards the substrate.

On the other hand, if the vaporization is arranged to take place very close to the surface of the substrate, the probability that some droplets will contact the surface in liquid form increases. The liquid form droplets do not necessarily undergo similar decomposition and/or chemical reactions as gas phase precursor vapor does. Therefore droplets hitting the surface in liquid form typically do not only result in the desired layer deposition, but generate random concentrations of defects to the coating. Accordingly, in order to appropriately control the quality of the coating process it is necessary to ensure most of the droplets are vaporized early enough before they contact the surface of the substrate.

When the coating is based on impaction based surface reactions on the surface of the substrate it is essential that droplets and the precursors do not vaporize before colliding to the surface of the substrate. When the coating is carried out at elevated temperatures it may be difficult to prevent or adjust the vaporization of the precursors from the droplets.

Controlling the balance of the vaporization such that good quality coating can be achieved with acceptable speed is important to industrially applicable coating processes.

### SUMMARY OF THE INVENTION

An object of the present invention is to provide an improved coating method and a coating apparatus so as to solve or at least alleviate the above mentioned prior art problem. The objects of the invention are achieved by a coating process and a coating apparatus, which are characterized by what is stated in the independent claims. The preferred embodiments of the invention are disclosed in the dependent claims.

The invention is based on the idea of forming a liquid mixture that comprises at least one precursor reacting on a surface of a substrate for forming a coating. The mixture may comprise precursors of a desired chemical vapour deposition reaction or precursors of a liquid phase surface reaction. The mixture is atomized into droplets that are transported in a defined process space towards a surface of a substrate to be coated. During transportation towards the surface of the substrate, the carrier substance is vaporized from the droplets with heat. The mixture is arranged to comprise a liquid form carrier substance, the composition of which is not a precursor of the chemical vapour deposition reaction, and is therefore dispensable. Furthermore, in the defined process space the boiling point of the carrier substance is lower than the boiling point of the precursor. This means that when the droplets are exposed to heat, the carrier substance will reach its boiling point first and during its vaporization the temperature of the droplet remains substantially constant. The precursor with higher boiling point is thus being transported towards the surface of the substrate in substantially constant temperature and in liquid form. In one embodiment when the carrier substance has vaporized and the heating continues, the temperature of the droplet reaches the boiling point of the precursor, and finally also the precursor vaporizes for providing a coating on the surface of the substrate through chemical vapour deposition reaction. In an alternative embodiment when the carrier substance has vaporized the droplet collides to the surface of the substrate and liquid phase surface reactions form a coating on the substrate surface.

Due to the carrier substance, the vaporization of the precursor takes place much closer to the surface of the substrate and therefore more precursor material is available for the chemical deposition reaction in the immediate vicinity of the surface. This speeds up the formation of the coating. Furthermore, due to the longer transportation in liquid form, there is less time and opportunity for the undesired particle formation within gas phase precursors. Accordingly, the quality of the coating is also improved. Additionally due to the carrier substance droplet may be transported to the surface of the substrate in liquid form in hot process conditions when the coating is performed by liquid phase surface reactions. This means that the vaporization of the precursors may be prevented before the droplet collides to the surface of the substrate. This helps to maintain the desired precursor composition in droplet.

The liquid mixture may naturally comprise a number of precursors to be used for one or more surface reactions. The carrier substance may be selected such that it vaporizes in the process environment before one selected precursor or before any number of selected precursor materials in the mixture. Advantageously the carrier substance is selected such that it vaporizes in the process environment before any of the precursors used in the coating process.

The embodiments of the invention provide further advantages that are discussed in more detail with each specific embodiment.

### BRIEF DESCRIPTION OF THE DRAWINGS

In the following the invention will be described in greater detail by means of preferred embodiments with reference to the attached drawings, in which

FIG. 1 shows schematically an exemplary embodiment of a coating apparatus;

FIG. 2 shows schematically another exemplary embodiment of a coating apparatus;

FIG. 3 illustrates a temperature curve of a droplet on its path towards the surface of the substrate.

### DETAILED DESCRIPTION OF THE INVENTION

The following embodiments are exemplary. Although the specification may refer to “an”, “one”, or “some” embodiment(s), this does not necessarily mean that each such reference is to the same embodiment(s), or that the feature only applies to a single embodiment. Single features of different embodiments may also be combined to provide other embodiments.

The present invention is applicable in any type of aerosol assisted chemical vapor deposition processes. All words and expressions of the following description are thus intended to illustrate, not to restrict, the embodiments and should therefore be interpreted in their broadest sense. Different embodiments of the invention will be described with elements and operations of a coating system where a layer is deposited on a heated and moving planar glass sheet without, however, restricting the embodiment to this particular device configuration and substrate material.

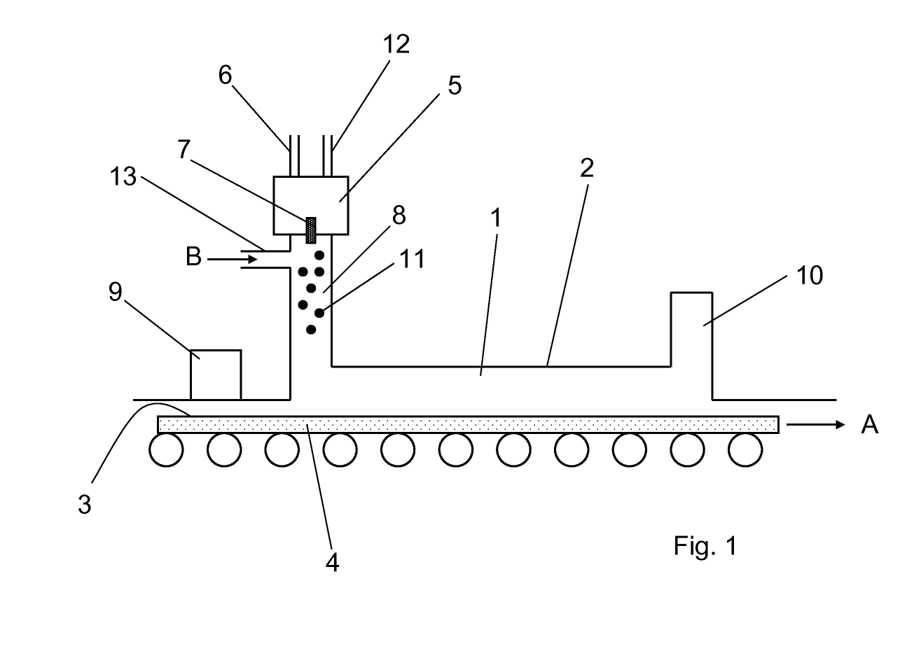

FIG. 1 shows schematically an exemplary embodiment of a coating apparatus according to the present invention. The coating apparatus comprises a deposition chamber 1, which is substantially isolated from the ambient atmosphere. The deposition chamber represents a process space that with its known volume and pressure provides a defined ambient environment for the coating process. The isolation from the ambient atmosphere may be implemented in many ways, generally known to a person skilled in the art. In the embodiment of FIG. 1, the deposition chamber 1 is formed of a combination of the solid walls 2 of the coating apparatus, the top surface 3 of the glass substrate 4 and gas curtains (not shown) in openings between then.

The coating process of the present embodiment is carried out preferably in normal air pressure. Normal air pressure means in this context atmospheric air pressure or a pressure substantially corresponding the atmospheric air pressure. However, depending on the type of materials and reactions used, other pressures may be applied, as well.

The deposition chamber 1 is interconnected with a mixture source 5. The mixture source 5 contains a liquid form mixture that through the interconnection may be fed into the deposition chamber 1. The mixture source 5 may be, for example, a replaceable container of readily mixed liquid, or a mixing apparatus that mixes materials fed to it via one or more material inlets 6, 12. In FIG. 1 the first inlet 6 is arranged to supply one or more precursors to the mixture source 5 and the second inlet 12 is arranged to supply one or more carrier substances to the mixture source 5.

The mixture refers here to a homogeneous matter that is composed of two or more substances, each retaining its own identifying properties. The mixture output to the deposition chamber comprises at least one precursor of the chemical vapor deposition reaction used for generating the desired layer on the surface 3 of the substrate 4. Precursor in this context refers to a substance that participates in any of the chemical reactions that are used to produce the other substance that forms the desired layer to the surface of the substrate.

The interconnection between the mixture source 5 and the deposition chamber 1 comprises at least one atomizer 7 for atomizing the liquid form mixture that is output from the mixture source 5 into droplets 11 to from a mist or aerosol 8, i.e. very small-sized drops of the input mixture. In the present embodiment, the atomizer 7 is advantageously arranged to produce droplets 11 with average diameter of less than 10 micrometers, preferably about 3 micrometers. The atomizer 7 refers to some kind of a dispenser that turns an input liquid into a cloud of droplets of the same liquid. In the present embodiment the atomizer 7 is a two fluid atomizer, in which atomizing gas is used for atomizing the liquid in to droplets 11.

The droplets 11 produced by the atomizer 7 are transported towards the surface 3 of the glass substrate 4 to be coated with the atomizer 7. In the present embodiment where the atomizer 7 operates with an atomizing gas, the trans-port effect may be achieved by forcing the aerosol or mist 8 from the atomizer out with velocity and directing the outlet of the atomizer towards the surface 3. Other methods for implementing or enhancing the transportation of the droplets 8 towards the surface 3 may be applied and are well known to a person skilled in the art. For example, an additional, directed gas flow may be used within the deposition chamber 1. FIG. 1 shows a separate gas flow B arranged in the atomization chamber for transporting the aerosol or mist 8 towards the substrate 4 surface 3. By using charged droplets 11 the transportation towards the surface 3 may be based on directed electric fields within the deposition chamber 1.

During their transportation, the droplets 11 of mixture are vaporized with heat. Accordingly, at least in some part of their path from the atomizer outlet towards the surface 3 the droplets are exposed to thermal energy. When a droplet absorbs this thermal energy, the temperature of the droplet increases. Eventually the temperature of the droplet reaches a point where the droplet is vaporized and the aerosol coming from the atomizer with liquid droplets has transformed into a completely gaseous form. It is noted, however, that each of the substances within the mixture vaporizes according to its own properties. Exposure to the thermal energy in the process space may be caused, for example, by a constant thermal flux in a heating zone crossing the transportation path, or a gradually increasing thermal flux on the path towards the surface 3.

In the present embodiment heating is implemented in the latter way, e.g. with a heating means 9 that heat the glass substrate 4 or the surface 3 or a surface layer of the glass substrate 4 to a desired temperature. The closer to the surface 3 of the substrate 4 a droplet comes, the higher is the thermal flux on the droplet. The heating means 9 of the embodiment may comprise a heating element with one or more flames, furnaces, heating resistor or heating gas flow that direct a flux of thermal energy on the glass substrate 4 or at least a surface layer of the surface 3 of the glass substrate 4 to be coated. One preferred alternative for heating means 9 is to use forced convection where a hot gas stream is directed towards the surface of the glass substrate 6. The heating means 9 of the present embodiment are placed such that the glass substrate 4 or a surface layer of the surface 3 of the glass substrate 4 to be coated may be heated before the surface 3 is exposed to the droplets 8. This is to ensure that the droplets 11 may be vaporized before they contact with the surface 3 to the coated. In an alternative embodiment the substrate 4 may come from an other process already at an elevated temperature such that there is no need for separate heating means and the substrate forms the heating means. The heating means may also be arranged to heat the process space instead of only the substrate.

The advantage from transferring the thermal energy needed for vaporizing the droplets from the hot or heated glass substrate itself is that no separate means are needed for vaporizing the droplets; the thermal energy needed for vaporizing the droplets is brought to the coating process with the glass substrate. However, the invention is not restricted to this type of transfer of thermal energy. Any types of device configurations that allow vaporization of the substances within the droplets during the transportation are applicable for the purpose. For example, the deposition chamber 1 may comprise one or more heating zones where the transported aerosol is exposed to radiated, conducted or convection heat. As will be discussed later, the heat transfer in the process space is adjusted in relation with the chemical composition of the droplets and the size of the droplets such that the material concentration of the substances that are precursors for the applied chemical deposition reaction is after vaporization as high as possible.

The coating may be formed when one or more of the vaporized precursor substances react directly with the surface of the substrate. Alternatively the coating may be formed on the surface of the substrate to be coated when two or more vaporized precursors first react with each other, after which the formed reaction products may react with the surface of the glass substrate to be coated. One or more of the vaporized precursors may also decompose into particles that are directed to the surface of the substrate such that at least part of the coating is formed by the particles.

In addition to the liquid droplets, one or more gases taking part to the formation of the coating may be supplied into the deposition chamber. Examples of such gases comprise oxygen gas or some other oxygen containing gas that takes part in formation of oxide coatings. The vaporized mixture and possible additional gases may be collected to an exhaust 10 and moved from the deposition chamber 1 with suction.

In the present embodiment, the thermal energy of the glass substrate 4 is adjusted to vaporize substantially all substances of the droplet mixture before the droplets 8 contact the surface 3. Typical temperatures of the glass surface are in the range of 550-610 degrees Celsius. The vaporized substances that are precursors of the applied chemical vapour deposition reaction further react with the surface 3 to be coated. According to the invention, the mixture fed from the mixture chamber 5 to the atomizer 10 comprises a liquid carrier substance, a liquid form material, the composition of which is not a precursor of the chemical vapour deposition reaction, and the boiling point of which in the deposition chamber is lower than the boiling point of at least one of the precursors of the chemical vapour deposition reaction. This means that the carrier substance vaporizes in the process environment before the at least one precursor of a chemical vapour deposition reaction.

Latent heat of vaporization corresponds to the amount of energy absorbed by a chemical substance during a change from liquid to gaseous state. A change of state in a substance occurs without changing its temperature, in a temperature specific for the substance and with latent heat of vaporization specific for the substance. The timing of vaporization of carrier substance may thus be controlled by selection of the substances in the mixture.

The liquid mixture may comprise a number of precursors to be used for one or more chemical vapour deposition reactions. The carrier substance may thus be selected such that its boiling point in the process environment is lower than one or more precursors of a chemical vapour deposition reaction. During transportation towards the surface of the substrate to be coated, the carrier substance then begins to boil before the one or more precursors. Boiling of the carrier substance keeps the temperature of the droplets in the boiling temperature of the carrier substance as long as the boiling takes place. Advantageously the carrier substance is selected such that its boiling point in the process environment is lower than any of the precursors of chemical vapour deposition reactions used in the coating process.

The timing of vaporization of the mixture substances may be further controlled by adjusting the heat in the chamber in relation with the latent heat of evaporation of the substances in the droplet. The latent heat of evaporation determines how much energy is required to vaporize the carrier substance, so the higher the heat, the shorter the time/interval the droplet remains in the boiling temperature of the carrier substance, and vice versa.

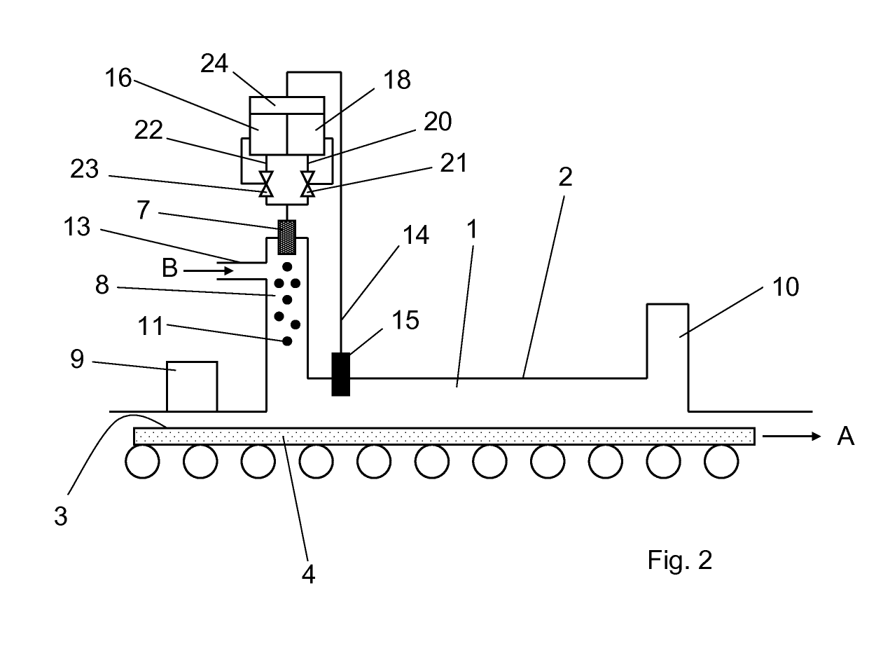

FIG. 2 shows an alternative embodiment of the present invention. In this embodiment the coating is provided by impaction based deposition of the droplets on a hot substrate 4. The reference numerals in FIG. 2 correspond to the same part of the apparatus as in FIG. 1, and they are not described again for simplicity. In this application the droplets are transported towards the surface of the substrate such that such that the droplets 11 collide to the surface 3 of the substrate 4 for providing a coating on the surface 3 of the substrate 4. During the transportation of the liquid droplets 11 the liquid carrier substance is vaporized from the droplets 11 before the droplets 11 collide to the surface 3 of the substrate 4.

The apparatus of FIG. 2 comprises a measurement arrangement arranged to measure the properties of the aerosol or mist 8 or the droplets 11. It should be noted that the same kind measurement apparatus may also be used in the apparatus of FIG. 1 and when the coating is carried out by chemical vapour deposition. The measurement arrangement comprises a measurement unit or detector 15 arranged to detect the properties of the mist or aerosol 8 or the droplets 11. The measurement unit or the detector 15 may be any know device suitable for detecting the properties of the mist or aerosol 8 or the droplets 11. The measurement unit or the detector 15 may be arranged to optically or acoustically measure the properties of the aerosol 8 or the composition of the droplets 11. Alternatively the measurement unit or the detector 15 may is arranged to detect humidity of the aerosol 8 or the concentration of droplets 11 in the aerosol. The measurement unit or the detector may use optical, acoustical, electrical, infrared or radiofrequency detection means for measuring the properties of the aerosol 8 or the droplets 11.

In a preferable embodiment the properties of the aerosol 8 or the droplets 11 are measured or detected in the vicinity of the substrate 4 surface 3. The measurement unit is thus preferably arranged to detect the aerosol 8 or droplet 11 properties at a distance of less than 5 mm, preferably less than 3 mm and more preferably less than 1 mm from the substrate 4 surface 3. The measurement unit 15 is preferably functionally connected to the means for forming a liquid mixture for adjusting the concentration of the carrier substance in the mixture on the bases of the measured aerosol or droplet properties. In FIG. 2 the measurement unit 15 is functionally connected via signal line 14 to an electronic unit 24. The electronic unit 24 is connected to a liquid dispensing device comprising a precursor container 16 and a carrier substance container 18. The precursors are supplied to the atomizer 7 via first supply line 22 having a first supply valve 23 and the carrier substance is supplied to the atomizer via a second supply line 20 having a second supply valve 21. The electronic unit 24 is arranged to the operated the valves 23, 21 based on the measurement signal from the measurement unit 15 for adjusting the vaporization of the carrier substance. Alternatively the measurement arrangement 14, 15 may be functionally connected to the one or more heaters 9 for adjusting the vaporization of the carrier substance from the droplets 11 during the transportation on the bases of the measurement aerosol properties. The measurement results may also be used in an alternative way for adjusting the vaporization of the droplets 11 or the carrier substance.

It should be understood that the measurement apparatus of FIG. 2 may also be utilized when the coating is carried out by chemical vapour deposition reactions and the droplets 11 are fully vaporized before they collide on the surface 3 of the substrate 4. The measurement unit may also be arranged to adjust the composition of the mixture in the mixture source 5 of FIG. 1. This may be achieved by adjusting the supply of carrier substance via the second inlet 12 into the mixture source 5.

For example acetone and methyl alcohol have quite similar boiling points, i.e. 50.5° C. and 64.7° C., respectively, but their latent heat of evaporation is quite different, i.e. 518 kJ/kg and 1100 kJ/kg, respectively. Thus methyl alcohol requires almost twice as much energy to vaporize as acetone, so its evaporation time/interval in same heat is considerably longer than of acetone.

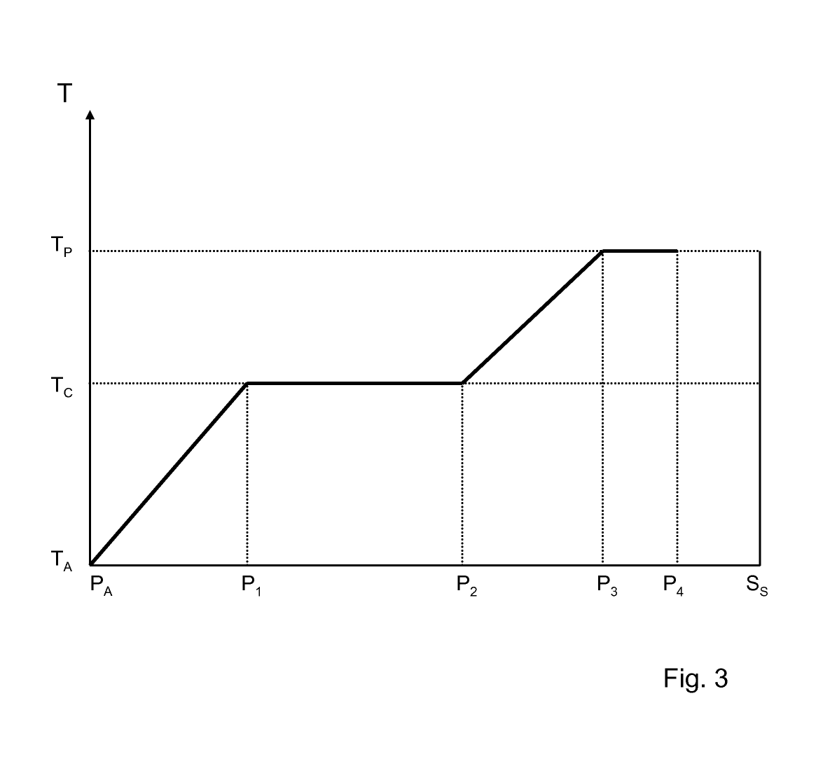

As an example, let us consider a simple case where the chemical vapour deposition process is based on one precursor that is comprised in the mixture. A droplet of the mixture thus comprises a portion of precursor substance and a portion of carrier substance, each retaining its own boiling point and latent heat of evaporation. FIG. 3 illustrates a temperature curve of a droplet of such mixture on its path from the point of atomization to the surface of the substrate in the exemplary embodiment of a coating apparatus shown in FIG. 1. Details for interpreting FIG. 3 may thus be referred from FIG. 1, as well.

The droplet is injected to the deposition chamber in a point of atomization P_{A} in an atomizing temperature T_{A}. If the atomization process does not include heating, the atomizing temperature T_{A} corresponds to the temperature within the mixture source. In the deposition chamber the droplet is exposed to thermal energy, and when the distance to the point of atomization P_{A} increases, the temperature T of the liquid form droplet rises. At some point P₁ the temperature of the droplet reaches the boiling point T_{c} of the carrier substance. The carrier substance within the droplet begins to vaporize and during the vaporization process, the droplet continues moving towards the substrate but thermal energy absorbed to the droplet is consumed by the state transfer of the carrier substance. Accordingly, the temperature of the droplet does not increase, but remains in T_{c} and at this temperature the precursor substance remains in liquid form.

When the portion of the carrier substance is fully vaporized in point P₂, its boiling ceases, the temperature T of the droplet begins to rise and in point P₃ eventually reaches the boiling point T_{P} of the precursor substance. After some boiling, at point P₄ the precursor substance is fully vaporized. However, due to the extended liquid form transportation, the concentration of the precursor substance within the zone between P₃ and P₄ is now much higher than it would be without the use of the carrier substance. With higher precursor concentrations the material transfer to the layer increases, and formation of the deposited layer on S_{S} is much faster than with conventional arrangements.

In an alternative embodiment in which the coating is carried out by impaction based deposition, the droplet will collide to the surface of the substrate at point P₂ such that the surface reactions for providing a coating on the substrate occur on the liquid phase on the substrate surface. This means that the precursors of the droplets are not vaporized, but the droplets will collide on the substrate surface when the carrier substance is essentially vaporized from the droplets. The use of carrier substance is preferable when the impaction based coating is performed on the hot substrate or at hot process conditions.

If the applied chemical vapour deposition process or impaction based coating process is based on more than one precursor, the carrier substance may be advantageously selected such that its boiling point is lower than the boiling point of any of the precursor materials.

It is noted that the temperature curve is illustrative only, the distances and temperatures depend on the configuration of the apparatus and the composition of the substances. Essentially, the pressure within the process space volume, the distribution of temperatures and the compositions of the substances included in the mixture are adjusted in combination such that a zone where the precursor materials of the reactions of the applied chemical vaporization process are in gaseous form is as close to the surface of the substrate as possible. Such adjustments are based on basic laws of phase transitions in a confined space and applicable to a person skilled in the art without undue burden or experimenting. In practical solutions this means that the precursor substance or the precursor substance with the highest boiling point reaches the boiling point at a distance of less than 5 mm, preferably less than 3 mm and more preferably less than 1 mm from the substrate surface, so that the capture ratio of the precursor molecules to the surface can be maximized.

For example, in the present embodiment of a glass substrate, the deposition process is based on reactions using a combination of Mono-butyl-tin-chloride (MBTC), Trifluoroacetic acid (TFA) and Methyl alcohol (MeOH) precursors. The mixture output from the mixture source may comprise a MBTC+TFA+MeOH composition, for example in ratio 60:30:10 percent of weight. In addition, the mixture comprises a portion of 5-50% of carrier substance, which may be one or several of the following: Acetone, Ethyl alcohol, Methyl alcohol, Propyl alcohol, Aniline, Benzene, Bromine, Carbon tetrachloride, Chloroform, Decane, Ethylene glycol, Iodine, Kerosene, Propylene glycol, Toluene, Turpentine or Water, which all have a boiling point lower than the boiling point of MBTC (between 46° C. and 197° C.) and latent heat of evaporation between roughly 160 kJ/kg and 2200 kJ/kg, so that the evaporation heat interval provides a great degree of freedom in optimizing the process parameters and equipment design. The boiling point of the applied carrier substance is lower than the boiling point of any of the precursor substances in the applied normal air pressure of the deposition chamber. The carrier substance is also neutral in respect of the gas phase surface reaction(s) designed to take place in a zone above the surface of the substrate (deposition zone), except that the carrier substance may work as a catalyst for the reaction. When the droplets of mixture begin to vaporize, the carrier substance boils first and for some time during its state transition keeps the temperature of the droplet lower than the boiling point of the precursor substances. Accordingly, the MBTC+TFA+MeOH substances are transported towards the deposition zone but stay in liquid form substantially until the portion of the carrier substance has been fully vaporized. A much higher concentration of MBTC+TFA+MeOH substances is thus trans-ported to the deposition zone.

It will be obvious to a person skilled in the art that, as the technology advances, the inventive concept can be implemented in various ways. The invention and its embodiments are not limited to the examples described above but may vary within the scope of the claims.

1-23. (canceled)

24. A process for coating a surface of a substrate, the process comprising:
forming a liquid coating mixture that comprises at least one precursor reacting on the surface of the substrate for forming a coating;
atomizing the coating mixture into droplets;
transporting the droplets towards the surface of the substrate such that the at least one precursor reacts on the surface of the substrate;
mixing to the mixture a liquid carrier substance, which is not a precursor, and the boiling point of which is lower than the boiling point of the precursor; and
heating the droplets during transportation towards the surface of the substrate for vaporizing the liquid carrier material or the liquid carrier material and the at least one precursor,
wherein the heating of the droplets is adjusted during transportation towards the surface of the substrate for adjusting the vaporization of the liquid carrier substance or the vaporization of the liquid carrier substance and the at least one precursor.

25. The process according to claim 24, wherein the process comprises:
including in the liquid mixture two or more precursors of the coating process;
mixing to the mixture the liquid carrier substance, the boiling point of which is lower than the boiling points of any of the precursors.

26. The process according to claim 24, wherein the liquid carrier substance is vaporized from the droplets before the droplets collide to the surface of the substrate.

27. The process according to claim 26, wherein the droplets are transported towards the surface of the substrate such that the droplets collide to the surface of the substrate for providing a coating on the surface of the substrate, or the liquid carrier substance is first vaporized from the droplets and then the at least one precursor is vaporized from the droplets, or the droplets are transported towards the surface of the substrate such that the droplets vaporize before colliding to the surface of the substrate for providing a coating on the surface of the substrate by chemical vapour deposition, or before the at least one precursor react on the surface of the substrate for providing a coating on the surface of the substrate by chemical vapour deposition.

28. The process according to claim 24, wherein the liquid carrier material or the liquid carrier material and the at least one precursor are vaporized from the droplets by heating the substrate or at least a surface layer of the substrate such that the thermal energy needed for the vaporization is provided by the substrate.

29. The process according to claim 24, wherein the concentration of the liquid carrier substance in the liquid coating mixture or in the droplets is adjusted for adjusting the vaporization of the liquid carrier substance or the vaporization of the liquid carrier substance and the at least one precursor.

30. The process according to claim 24, wherein the vaporization of the droplets is adjusted such that a zone where the precursor or all precursors are substantially in gaseous form is within a 5 mm range from the surface of the substrate, or the pressure in the process space, heat of vaporization and the composition of substances in the mixture in combination are adjusted such that a zone where the precursor or all precursors are substantially in gaseous form is within a 5 mm range from the surface of the substrate.

31. The process according to claim 24, wherein properties of a mist formed by the droplets is measured.

32. The process according to claim 31, wherein one or more of the following is adjusted: the heating of the droplets, the concentration of the liquid carrier substance in the liquid coating mixture or in the droplets, or pressure in the process space for adjusting the vaporization of the droplets on the basis of the measured mist properties.

33. A coating apparatus for coating a surface of a substrate, the coating apparatus comprising:
means for forming a liquid mixture comprising at least one precursor reacting on the surface of the substrate the mixture comprises a liquid carrier substance, which is not a precursor, and the boiling point of which is lower than the boiling point of the precursor;
one or more atomizers arranged to atomize the mixture into droplets for forming an aerosol; and
means for transporting the aerosol towards the surface of the substrate such that the at least one precursor reacts on the surface of the substrate,
wherein the apparatus further comprises measurement arrangement arranged to measure the properties of the aerosol and one or more heaters for providing thermal energy for vaporizing the droplets during the transportation.

34. The apparatus according to claim 33, wherein apparatus further comprises one or more heaters configured to heat the substrate or at least the surface layer of the substrate for providing thermal energy for vaporizing the droplets during the transportation, or that the substrate is at elevated temperature and forms a heater for providing thermal energy for vaporizing the droplets.

35. The apparatus according to claim 33, wherein in that the means for forming a liquid mixture are arranged to add the liquid carrier substance to the mixture.

36. The apparatus according to claim 33, wherein the apparatus is arranged to vaporize the liquid carrier substance from the droplets before the precursors react on the surface of the substrate.

37. The apparatus according to claim 36, wherein the apparatus is arranged to:
transport the aerosol towards the surface of the substrate such that droplets collide to the surface of the substrate for providing a coating on the surface of the substrate; or
transport the aerosol towards the surface of the substrate such that first the liquid carrier substance is vaporized from the droplets and then vaporizing the at least one precursor from the droplets before the before colliding to the surface of the substrate for providing a coating on the surface of the substrate by chemical vapour deposition.

38. The apparatus according to claim 33, wherein measurement arrangement is arranged to optically or acoustically measure the properties of the aerosol or the composition of the droplets, or that the measurement arrangement is arranged to detect humidity of the aerosol or the concentration of droplets in the aerosol, or that the measurement arrangement is arranged to use infrared or radiofrequency detector for measuring the properties of the aerosol.

39. The apparatus according to claim 33, wherein measurement arrangement is functionally connected to the means for forming a liquid mixture for adjusting the concentration of the carrier substance in the mixture on the bases of the measurement aerosol properties, or that the measurement arrangement is functionally connected to the one or more heaters for adjusting the vaporization of the carrier substance from the droplets during the transportation on the bases of the measurement aerosol properties.

40. The process according to claim 25, wherein the liquid carrier substance is vaporized from the droplets before the droplets collide to the surface of the substrate.

41. The process according to claim 40, wherein the droplets are transported towards the surface of the substrate such that the droplets collide to the surface of the substrate for providing a coating on the surface of the substrate, or the liquid carrier substance is first vaporized from the droplets and then the at least one precursor is vaporized from the droplets, or the droplets are transported towards the surface of the substrate such that the droplets vaporize before colliding to the surface of the substrate for providing a coating on the surface of the substrate by chemical vapour deposition, or before the at least one precursor react on the surface of the substrate for providing a coating on the surface of the substrate by chemical vapour deposition.

42. The apparatus according to claim 34, wherein in that the means for forming a liquid mixture are arranged to add the liquid carrier substance to the mixture.
